(19) United States
(12) Patent Application Publication
(10) Pub. No.: US 2025/0142802 A1
(43) Pub. Date: May 1, 2025

(54) SEMICONDUCTOR DEVICE AND METHOD FOR MANUFACTURING THE SAME

(71) Applicant: SK hynix Inc., Gyeonggi-do (KR)

(72) Inventor: Seiyon KIM, Gyeonggi-do (KR)

(21) Appl. No.: 18/928,825

(22) Filed: Oct. 28, 2024

(30) Foreign Application Priority Data
Oct. 27, 2023 (KR) 10-2023-0146105

(51) Int. Cl. H10B 12/00

(52) U.S. Cl. CPC H10B 12/00

(57) ABSTRACT

A semiconductor device includes a first bit line extending in a first direction; a first transistor configured to include a first gate that extends in a second direction perpendicular to the first direction and a first active region; a second bit line extending in the first direction; and a second transistor configured to include a second active region connected to the second bit line and a second gate overlapping with the second active region. The first active region includes: a horizontal portion configured to contact the first bit line; and a vertical portion that contacts the horizontal portion and extends in a third direction perpendicular to each of the first direction and the second direction. The second gate contacts the vertical portion.

### CROSS-REFERENCE TO RELATED APPLICATION

This patent application claims the priority and benefits of Korean patent application No. 10-2023-0146105, filed on Oct. 27, 2023, the disclosure of which is incorporated herein by reference in its entirety.

### TECHNICAL FIELD

The technology and embodiments disclosed in the present disclosure generally relate to a semiconductor device, and more particularly to a semiconductor device including memory cells.

### BACKGROUND

As miniaturization and higher degrees of integration of semiconductor devices have become major issues, memory cells included in semiconductor devices can be formed to have three-dimensional (3D) patterns. Miniaturized memory cells with three-dimensional (3D) patterns can be equipped with configurations that improve operation characteristics of the memory cells.

### SUMMARY

Various embodiments of the present disclosure relate to a semiconductor memory device that includes two transistors and has a higher degree of integration.

Various embodiments of the present disclosure relate to a semiconductor memory device that prevents signal interference between word lines.

In accordance with an embodiment of the present disclosure, a semiconductor device may include a first bit line extending in a first direction; a first transistor configured to include a first gate that extends in a second direction perpendicular to the first direction and a first active region; a second bit line extending in the first direction; and a second transistor configured to include a second active region connected to the second bit line and a second gate overlapping with the second active region. The first active region may include a horizontal portion configured to contact the first bit line; and a vertical portion that contacts the horizontal portion and extends in a third direction perpendicular to each of the first direction and the second direction. The second gate may contact the vertical portion.

In some embodiments, the first gate may be connected to a first word line.

In some embodiments, the semiconductor device may further include a second word line extending in the second direction, wherein the second word line is connected to the second active region.

In some embodiments, the second transistor may be configured to share the second active region with another adjacent second transistor.

In some embodiments, the second gates included in the second transistors sharing the second active region may contact vertical portions of different first transistors, respectively.

In some embodiments, source and/or drain regions of the first transistor may be included in the first active region, and source and/or drain regions of the second transistor may be included in the second active region.

In some embodiments, source and/or drain regions of the first transistor may be connected to either the second gate or the first bit line, and source and/or drain regions of the second transistor may be connected to either the second bit line or a second word line extending in the second direction.

In some embodiments, the semiconductor device may further include a plurality of memory cells, each of which includes two first transistors and two second transistors.

In some embodiments, the two first transistors may be connected in parallel to each other; and the two second transistors may be connected in series to each other.

In some embodiments, each of the first active region and the second active region may include indium gallium zinc oxide (IGZO).

In some embodiments, the semiconductor device may further include a third gate disposed between vertical portions respectively included in adjacent first active regions, and extending in the second direction.

In some embodiments, the third gate may be configured to receive a ground voltage as an input.

In some embodiments, the first gate may include a first sub-gate and a second sub-gate extending in the second direction; and the vertical portion may be disposed between the first sub-gate and the second sub-gate.

In some embodiments, the same activation voltage may be provided to the first sub-gate and the second sub-gate.

In some embodiments, the semiconductor device may further include a first gate insulation layer disposed between the first gate and the first active region; and a second gate insulation layer disposed between the second gate and the second active region.

In some embodiments, the second active region may be connected to the second bit line through a via contact.

In accordance with another embodiment of the present disclosure, a semiconductor device may include: a first bit line extending in a first direction; a first gate extending in a second direction perpendicular to the first direction; a first active region configured to include a vertical portion extending in a third direction perpendicular to each of the first direction and the second direction, and a horizontal portion extending in the first direction while contacting the first bit line; a first gate insulation layer disposed between the first gate and the first active region; a second gate configured to contact the vertical portion; a second gate insulation layer disposed over the second gate; a second active region disposed over the second gate insulation layer; a second bit line extending in the first direction and connected to the second active region; and a second word line extending in the second direction and connected to the second active region.

In some other embodiments, the semiconductor device may further include another first active region configured to contact the first bit line while having the same shape as the first active region; and another second gate configured to contact the other first active region, wherein the second gate insulation layer is disposed between the second active region and the other second gate.

In some other embodiments, the semiconductor device may further include another first gate extending in the second direction; and another first gate insulation layer disposed between the other first gate and the other first active region.

In some other embodiments, the semiconductor device may further include a third gate disposed between the first active region and the other first active region, and extending in the second direction.

In some other embodiments, the semiconductor device may further include another second word line extending in the second direction and connected to the second active region.

It is to be understood that both the foregoing general description and the following detailed description of the disclosed embodiments are illustrative and descriptive and are intended to provide further description of the embodiments of the present disclosure as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1A is a schematic perspective view illustrating a semiconductor device according to an embodiment of the present disclosure.

FIG. 1B is a schematic perspective view illustrating a semiconductor device according to another embodiment of the present disclosure.

FIG. 2A is a cross-sectional view illustrating the semiconductor device taken along a first cutting line shown in FIG. 1A according to an embodiment of the present disclosure.

FIG. 2B is a cross-sectional view illustrating the semiconductor device taken along the second cutting line shown in FIG. 1B according to another embodiment of the present disclosure.

FIG. 3 is an equivalent circuit diagram illustrating a memory cell included in the semiconductor device according to an embodiment of the present disclosure.

FIGS. 4A to 4Q are cross-sectional views illustrating a method for manufacturing the semiconductor device according to an embodiment of the present disclosure.

FIGS. 5A to 5M are cross-sectional views illustrating a method for manufacturing the semiconductor device according to another embodiment of the present disclosure.

### DETAILED DESCRIPTION

The present disclosure provides embodiments and examples of a semiconductor device including memory cells that may be used in configurations to substantially address one or more technical or engineering issues and to mitigate limitations or disadvantages encountered in some other semiconductor devices.

Some embodiments of the present disclosure relate to a semiconductor memory device that includes two transistors and has a higher degree of integration. Some embodiments of the present disclosure relate to a semiconductor memory device that prevents signal interference between word lines. In recognition of the issues above, the embodiments of the present disclosure may provide a semiconductor device that has three-dimensional (3D) channels to improve the degree of integration. Additionally, the embodiments of the present disclosure may provide the semiconductor device having at least one transistor that operates as a storage element, resulting in a simplified fabrication process

Reference will now be made in detail to the embodiments of the present disclosure, examples of which are illustrated in the accompanying drawings. Wherever possible, the same reference numbers will be used throughout the drawings to refer to the same or like parts. While this disclosure is susceptible to various modifications and alternative forms, specific embodiments thereof are shown by way of example in the drawings. However, this disclosure should not be construed as being limited to the embodiments set forth herein.

Hereinafter, various embodiments of the present disclosure will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized.

In the following description, a detailed description of related known configurations or functions incorporated herein will be omitted to avoid obscuring the subject matter.

The terminology used herein is for the purpose of describing particular embodiments only and is not intended to be limiting of the scope of the present disclosure. As used herein, the singular forms are intended to include the plural forms as well, unless the context clearly indicates otherwise. It will be further understood that the terms “comprises”, “includes”, “including”, and/or “comprising,” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items.

Hereinafter, a semiconductor device and a method for manufacturing the same according to embodiments of the present disclosure will be described with reference to the attached drawings.

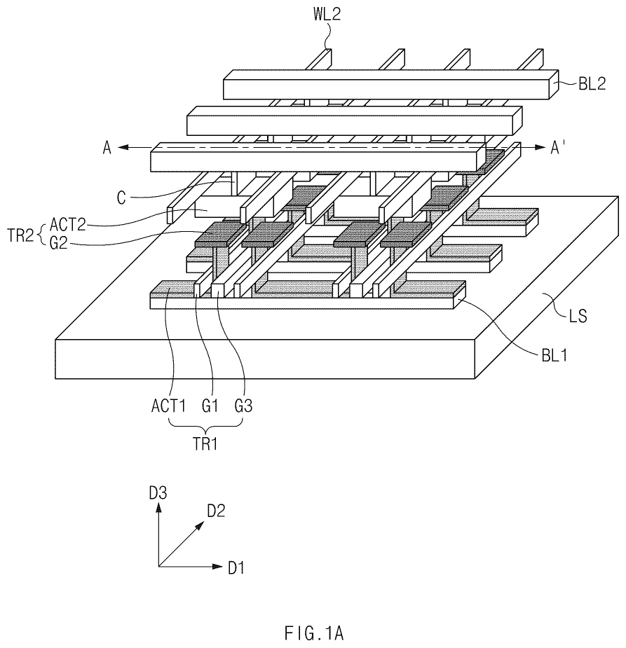

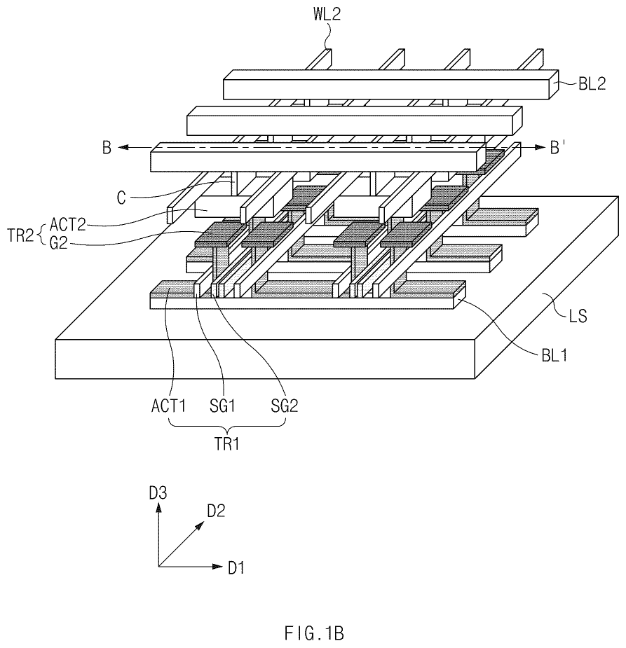

FIG. 1A is a schematic perspective view illustrating a semiconductor device 100a according to an embodiment of the present disclosure.

FIG. 1B is a schematic perspective view illustrating a semiconductor device 100b according to another embodiment of the present disclosure.

The structures of the semiconductor devices 100a, 100b will hereinafter be described with reference to FIGS. 1A and 1B, but redundant description thereof will herein be omitted.

Each of the semiconductor devices 100a, 100b may include a substrate LS and a plurality of memory cells formed over the substrate LS while being repeatedly arranged over the substrate LS. Each memory cell may have a three-dimensional (3D) structure.

More specifically, each of the memory cells included in the semiconductor devices 100a, 100b may include a first transistor TR1 and a second transistor TR2.

The substrate LS may be a material suitable for semiconductor processing. The substrate LS may include at least one of a conductive material, an insulation material (also called a dielectric material), and a semiconductor material (also called a semiconductive material). In some embodiments, a plurality of material layers may be formed over the substrate LS.

The substrate LS may include a semiconductor material. For example, the substrate LS may be formed of a semiconductor material containing silicon. The substrate LS may include silicon, monocrystalline silicon, amorphous silicon, silicon germanium, monocrystalline silicon germanium, polycrystalline silicon germanium, carbon-doped silicon, a combination thereof, or multilayers thereof. The substrate LS may also include other semiconductor materials such as germanium. The substrate LS may include a group III/V semiconductor substrate, for example, a compound semiconductor substrate such as GaAs.

The substrate LS may include a silicon on insulator (SOI) substrate. In another embodiment, the substrate LS may include a peripheral circuit region (not shown) located at a lower portion thereof. The peripheral circuit region may include a plurality of control circuits for controlling memory cells. At least one control circuit of the peripheral circuit region may include an N-channel transistor, a P-channel transistor, a CMOS circuit, or a combination thereof. At least one control circuit of the peripheral circuit region may include an address decoder circuit, a read circuit, a write circuit, etc.

At least one control circuit included in the peripheral circuit region may include a planar channel transistor, a recess channel transistor, a buried gate transistor, a fin channel transistor (FinFET), and the like.

At least one control circuit included in the peripheral circuit region may be electrically connected to bit lines BL1, BL2, a first gate G1, or a second word line WL2. The peripheral circuit region may include a sense amplifier (sense-amp), and the sense amplifier (sense-amp) may be electrically connected to the bit lines BL1, BL2. Although not shown, a multi-level metal interconnection may be disposed between the substrate LS and the memory cells. The peripheral circuit region, the bit lines BL1, BL2, the first gate G1 or the second word line WL2 may be connected to each other through the multi-level metal interconnection (MLM).

Referring to FIG. 1A, the first transistor TR1 according to an embodiment may include a first gate G1, a first active region ACT1, and a third gate G3. The second transistor TR2 may include a second gate G2 and a second active region ACT2.

The first active region ACT1 included in the first transistor TR1 may be connected to the first bit line BL1 extending in a first direction D1, and may be connected to the second gate G2 included in the second transistor TR2.

The first gate G1 may extend in a second direction D2 perpendicular to the first direction D1. The first gate G1 may be connected to the first word line (not shown).

The third gate G3 may extend in the second direction D2, and may be disposed between vertical portions respectively included in two adjacent first active regions ACT1.

Each of the first gates G1 may be connected to the first word line (not shown) and may receive an activation voltage corresponding to a word line activation signal from the first word line.

The third gate G3 may operate as a back gate that blocks interference between adjacent first gates G1.

The third gate G3 may, for example, include a metal, a metal mixture, a metal alloy, titanium nitride, tungsten, polysilicon, or a combination thereof.

The first active region ACT1 may include a horizontal portion connected to the first bit line BL1 and a vertical portion extending in a third direction D3 perpendicular to the second direction D2. The vertical portion may contact the horizontal portion at one side thereof, and may contact the second gate G2 at the other side thereof. For example, the first active region ACT1 may include one horizontal portion and two vertical portions.

The second gate G2 may contact one vertical portion. Additionally, the second gate G2 may be arranged in a matrix structure on one surface of the substrate LS, and may be disposed at locations corresponding to the respective vertical portions.

The second active region ACT2 included in the second transistor TR2 may be located above the second gate G2 and may be electrically isolated from the second gate G2.

The second active region ACT2 may be connected to the second bit line BL2 extending in the first direction D1, and may be connected to the second word line WL2 extending in the second direction D2.

The second active region ACT2 and the second bit line BL2 may be connected through at least one via contact C.

The active regions ACT1, ACT2 and the gates G1, G2, G3 may be electrically isolated from each other by insulation layers (not shown). Additionally, the gates G1, G2, G3, the bit lines BL1, BL2, and the second word lines WL2 may be electrically isolated from each other by insulation layers (not shown).

The insulation layer may include, for example, silicon oxide, silicon nitride, metal oxide, metal oxynitride, metal silicate, high-k material, ferroelectric material, anti-ferroelectric material, or a combination thereof. In some other embodiments, the insulation layer may include SiO₂, Si₃N₄, HfO₂, Al₂O₃, ZrO₂, AlON, HfON, HfSiO, HfSiON, and the like, or may include SiCO, and the like.

There may be a difference in composition between the insulation layers according to the locations of the insulation layers. For example, the insulation layer disposed between the first gates G1 may include silicon oxide, and the insulation layer disposed between the first gate G1 and the first active region ACT1 may include a high-k material.

Each of the first and second bit lines BL1 and BL2 may include a conductive material.

Each of the bit lines BL1, BL2 may include a silicon-based material, a metal-based material, or a combination thereof. Each of the bit lines BL1, BL2 may include polysilicon, metal, metal nitride, metal silicide, or a combination thereof.

Each of the bit lines BL1, BL2 may include polysilicon, titanium nitride, tungsten (W), or a combination thereof. For example, the bit lines BL1, BL2 may include polysilicon doped with N-type impurities or titanium nitride (TiN).

Each of the bit lines BL1, BL2 may include a stacked structure (TiN/W) of titanium nitride (TiN) and tungsten (W). Each of the bit lines BL1, BL2 may further include an ohmic contact layer formed of, for example, a metal silicide.

The first and second bit lines BL1 and BL2 may be located above the substrate LS, and may be horizontally oriented in the first direction D1.

Each of the first and second bit lines BL1 and BL2 may be referred to as a laterally-oriented bit line or a laterally-extended bit line.

The plurality of the first transistors TR1 arranged in the first direction D1 may share one first bit line BL1. Additionally, the plurality of the second transistors TR2 arranged in the first direction D1 may share one second bit line BL2.

The plurality of the first transistors TR1 arranged in the second direction D2 may share the first gate G1 extending in the second direction D2. Additionally, the plurality of the second transistors TR2 arranged in the second direction D2 may share one second word line WL2.

Each of the first gate G1 and the second word line WL2 may include a metal, a metal mixture, a metal alloy, titanium nitride, tungsten, polysilicon, or a combination thereof.

The first gate G1 may extend in a direction perpendicular to the bit line BL1, and the second word line WL2 may extend in a direction perpendicular to the bit line BL2.

Each of the first active region ACT1 and the second active region ACT2 may include a semiconductor material or an oxide semiconductor material. Each of the active regions ACT1, ACT2 may include a plurality of impurity regions. Each of the impurity regions may include source and/or drain regions of each transistor TR1, TR2.

Each of the active regions ACT1, ACT2 may include doped polysilicon, undoped polysilicon, amorphous silicon, IGZO (amorphous indium gallium zinc oxide semiconductor), indium zinc oxide (IZO), indium tin oxide (ITO), indium oxide (InO₃), and the like.

Referring to FIG. 1B, the first transistor TR1 according to another embodiment may include a first sub gate SG1 and a first active region ACT1. The second transistor TR2 may include a second gate G2 and a second active region ACT2.

The first active region ACT1 included in the first transistor TR1 may be connected to the first bit line BL1 extending in the first direction D1, and may be connected to the second gate G2 included in the second transistor TR2.

Unlike the embodiment illustrated in FIG. 1A, the first transistor TR1 shown in FIG. 1B may include a first sub-gate SG1 and a second sub-gate SG2 that extend in the second direction D2 perpendicular to the first direction D1. In the embodiment of FIG. 1B, a pair of the first sub-gate SG1 and the second sub-gate SG2 may correspond to the first gate G1 shown in FIG. 1A. A pair of the first sub-gate SG1 and the second sub-gate SG2 shown in FIG. 1B may operate as the first gate G1 shown in FIG. 1A.

In the embodiment of FIG. 1B, one pair of the first sub-gate SG1 and the second sub-gate SG2 may be connected to one first word line (not shown). One pair of the first sub-gate SG1 and the second sub-gate SG2 may receive an activation voltage corresponding to a word line activation signal from the first word line.

The first transistor TR1 including two sub-gates SG1, SG2 may be referred to as a double gate transistor.

Since the first transistor TR1 includes two sub-gates SG1, SG2, the first word line WL1 may be provided as a double gate structure. As the first word line WL1 has a double gate structure, channel regions may be formed on both sides of the vertical portion included in the first active region ACT1. As the two channel regions are formed, electron mobility within the channel regions may increase, and the semiconductor device may be controlled with the increased electron mobility at a low activation voltage.

The shape of the first active region ACT1 and the shape of the second transistor TR2 are the same as those of the embodiment described with reference to FIG. 1A, and as such redundant description thereof will herein be omitted for brevity.

Likewise, the connection relationship between the transistors TR1, TR2 and the bit lines BL1, BL2 is also the same as those of the embodiment described with reference to FIG. 1A, and as such redundant description thereof will herein be omitted for brevity.

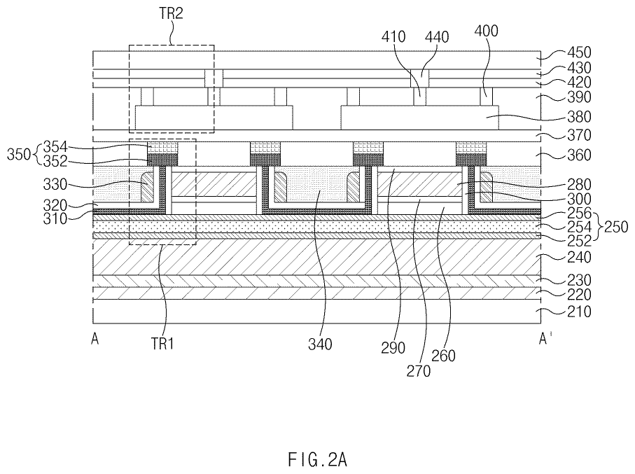

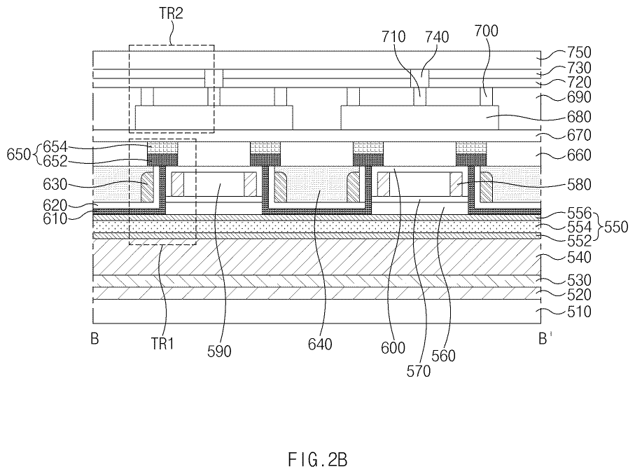

FIG. 2A is a cross-sectional view 200a illustrating the semiconductor device taken along a first cutting line A-A′ shown in FIG. 1A according to an embodiment of the present disclosure.

Referring to FIG. 2A, the semiconductor device may include a substrate layer 210, a first interlayer insulation layer 220 formed over the substrate layer 210, and a second interlayer insulation layer 230 formed over the first interlayer insulation layer 220.

The substrate layer 210 may include a silicon semiconductor material. For example, the substrate layer 210 may include silicon, monocrystalline silicon, polysilicon, amorphous silicon, silicon germanium, monocrystalline silicon germanium, polycrystalline silicon germanium, carbon-doped silicon, and the like.

The substrate layer 210 may include a plurality of control circuits configured for controlling the operation of the semiconductor device. A region of the substrate layer 210 where the control circuits are provided may be referred to as a peripheral circuit region.

The first interlayer insulation layer 220 formed over the substrate layer 210 may include a metal silicide material such as cobalt silicide (CoSi). The first interlayer insulation layer 220 is provided in the semiconductor device, so that the operation resistance of the semiconductor device may decrease.

The first interlayer insulation layer 220 may protect the substrate layer 210. The first interlayer insulation layer 220 may prevent damage to the substrate layer 210 during a semiconductor fabrication process.

The second interlayer insulation layer 230 may include a layer containing silicon nitride. Since the second interlayer insulation layer 230 includes silicon nitride, damage to the substrate layer 210 may be prevented during a high-temperature semiconductor fabrication process.

The third interlayer insulation layer 240 may be disposed over the second interlayer insulation layer 230. The third interlayer insulation layer 240 may contain silicon oxide, and the like, may operate as an insulation layer together with the second interlayer insulation layer 230, and may electrically isolate the control circuits included in the substrate layer 210 from the first bit line 250.

The first bit line 250 disposed over the third interlayer insulation layer 240 may include a plurality of layers. For example, the first bit line 250 may include a first sub-bit line layer 252 including titanium nitride (TiN), a second sub-bit line layer 254 including tungsten (W), and a third sub-bit line layer 256 including titanium nitride (TiN).

Since the first bit line 250 includes a plurality of layers, the operation resistance of the semiconductor device may be adjusted.

After depositing the plurality of layers, the first bit line 250 may be formed through an etching process that uses a mask.

Adjacent first bit lines 250 may be electrically isolated from each other by a first bit-line isolation layer (not shown). The first-bit line isolation layer may include a plurality of layers including silicon nitride or silicon oxide.

A fourth interlayer insulation layer 260 and a fifth interlayer insulation layer 270 may be disposed above the first bit line 250.

Each of the fourth interlayer insulation layer 260 and the fifth interlayer insulation layer 270 may include a layer containing at least one of silicon oxide, carbon-containing silicon oxide, and silicon nitride.

As the fourth interlayer insulation layer 260 and the fifth interlayer insulation layer 270 are provided in the semiconductor device, the third gate 280 and the first bit line 250 may be electrically isolated from each other.

The third gate 280 may include a metal, a metal mixture, a metal alloy, titanium nitride, tungsten, polysilicon, or a combination thereof. For example, the third gate 280 may include titanium nitride. The third gate 280 may extend in the second direction D2 shown in FIG. 1A.

A sixth interlayer insulation layer 290 may be disposed over the third gate 280. The sixth interlayer insulation layer 290 may be used as a mask (hereinafter referred to as an etch mask) of an etching process required to form the third gate 280. The sixth interlayer insulation layer 290 may include, for example, silicon nitride.

The third gate insulation layer 300 may be disposed at a sidewall of the vertical portion included in the first active region 310, and may electrically isolate the third gate 280 from the vertical portion.

The third gate insulation layer 300 may include, for example, silicon oxide.

The third gate insulation layer 300 may be formed along the sidewall of the third gate 280, and may be formed to extend in the second direction D2 shown in FIG. 1A.

At least a portion of the first active region 310 may be arranged to contact the first bit line 250. The horizontal portion included in the first active region 310 may contact the first bit line 250.

The first active region 310 may include two vertical portions and one horizontal portion. The vertical portion may be formed to extend in the third direction D3 shown in FIG. 1A.

The first active region 310 including two vertical portions and one horizontal portion may be repeatedly arranged in a matrix structure in the first direction D1 and the second direction D2 shown in FIG. 1A.

For example, the first active region 310 may include an oxide semiconductor material. The oxide semiconductor material may include indium gallium zinc oxide (IGZO).

According to another embodiment, the first active region 310 may include doped polysilicon, undoped polysilicon, amorphous silicon, indium zinc oxide (IZO), indium tin oxide (ITO), indium oxide (InO₃), and the like.

Since IGZO has low leakage current characteristics and the first active region 310 is formed of IGZO, a semiconductor device with low standby power can be implemented. Also, using IGZO for the first active region 310 reduces the difficulty of the fabrication process, and the first active region 310 with a three-dimensional (3D) structure including vertical and horizontal portions may be easily formed.

The source region and the drain region of the first transistor TR1 may be provided in the first active region 310. When an activation voltage is provided to the first gate 330 of the first transistor TR1, a channel region is formed in the first active region 310 so that electron movement may occur between the source region and the drain region.

The first gate insulation layer 320 may be disposed between the first active region 310 and the first gate 330. For example, the first gate insulation layer 320 may include silicon oxide. The first gate 330 and the first active region 310 may be electrically isolated from each other by the first gate insulation layer 320.

The first gate 330 may include a metal, a metal mixture, a metal alloy, titanium nitride, tungsten, polysilicon, or a combination thereof. For example, the first gate 330 and the third gate 280 may include titanium nitride. The first gate 330 may extend in the second direction D2 shown in FIG. 1A.

When an activation voltage is provided to the first gate

330, a ground voltage may be provided to the third gate 280. For example, the activation voltage may be a first word line activation voltage. The first gate 330 may operate as the first word line.

When the ground voltage is provided to the third gate 280, the third gate 280 may provide a back-bias voltage to the semiconductor device.

The third gate 280 may be disposed between two adjacent first gates 330 and the first active regions 310 corresponding to the first gates 330.

As the ground voltage is provided to the third gate 280, adjacent first gates 330 may be electrically isolated from each other.

Such electrical isolation between the adjacent first gates 330 may mean that electrical interference between the adjacent first gates 330 is blocked.

As the semiconductor device is reduced in size, the distance between the first gates 330 may become shorter. When the distance between the first gates 330 is shortened, a coupling phenomenon may occur between the adjacent first gates 330 due to a first word line activation voltage provided to each of the first gates 330. Due to the coupling phenomenon, unexpected errors may occur during data read/write operations of the semiconductor device.

In some embodiments, the third gate 280 is disposed between the first gates 330 and the ground voltage is provided to the third gate 280 so that the coupling phenomenon between the first gates 330 is prevented, thereby improving the operation characteristics of the semiconductor device.

In addition, the third gate 280 provided with a ground voltage may provide a back-bias voltage to the semiconductor device, thereby efficiently suppressing leakage current (e.g., gate induced drain leakage (GIDL), etc.) and improving the electrical characteristics of the semiconductor device.

The seventh interlayer insulation layer 340 may include an insulation layer disposed between two adjacent first gates 330. The adjacent first gates 330 may be electrically isolated from each other by the seventh interlayer insulation layer 340. For example, the seventh interlayer insulation layer 340 may include silicon oxide, silicon nitride, or the like.

Second gate 350 may be arranged to contact one side of the vertical portion included in the first active region 310. The second gate 350 may include a plurality of layers.

For example, the second gate 350 may include a lower gate layer 352 and an upper gate layer 354.

The lower gate layer 352 may include the same material as the first active region 310. For example, the lower gate layer 352 may include an oxide semiconductor such as IGZO.

Since the lower gate layer 352 includes the same material as the first active region 310, interfacial resistance between the second gate 350 and the first active region 310 may be reduced.

The upper gate layer 354 formed over the lower gate layer 352 may include a conductive material such as a metal nitride material or a metal material. The operation characteristics (e.g., active voltage, etc.) of the second transistor TR2 may be controlled by adjusting the characteristics of constituent materials included in the upper gate layer 354.

The eighth interlayer insulation layer 360 may electrically isolate adjacent second gates 350 from each other. The eighth interlayer insulation layer 360 may be formed to surround each of the second gates 350, and may be disposed between the second gates 350.

The eighth interlayer insulation layer 360 may include, for example, silicon nitride or silicon oxide.

The second gate insulation layer 370 may include an insulation layer formed over the second gates 350. The second gate insulation layer 370 may be disposed to overlap the second gates 350, and may include silicon oxide. The second gates 350 and the second active regions 380 may be electrically isolated from each other by the second gate insulation layer 370.

Each of the second active regions 380 may be shared by two adjacent second transistors TR2. As can be seen from FIG. 2A, one second active region 380 may overlap two second gates 350, and an activation voltage may be provided to the second gates 350 at different time points.

The source region and the drain region of the second transistor TR2 may be provided in each of the second active regions 380. When the activation voltage is provided to the second gates 350 of the second transistor TR2, a channel region may be formed in each of the second active regions 380 so that electron movement may occur between the source region and the drain region of the second active region 380.

In some embodiments, since each of the second transistors TR2 is formed in a vertical shape, the second transistors TR2 can be easily stacked within a small-sized area. In addition, since the second transistor TR2 instead of a capacitor is used as a data storage element, a process of forming the data storage element can be simplified and the degree of freedom of a layout structure of the semiconductor device can be increased.

The ninth interlayer insulation layer 390 may electrically isolate adjacent second active regions 380 from each other. The ninth interlayer insulation layer 390 may include, for example, silicon nitride or silicon oxide.

At least one second word line 400 and at least one first via contact 410 may be formed by etching the ninth interlayer insulation layer 390. Each of the second word lines 400 and each of the first via contacts 410 may include a conductive material such as a metal or metal nitride. The first via contacts 410 may penetrate the ninth interlayer insulation layer 390 in the vertical direction D3.

The second word lines 400 may extend in the second direction D2 shown in FIG. 1A. The first via contacts 410 may be repeatedly arranged in the first direction D1 and the second direction D2, and each of the second active regions 380 may be connected to the first via contacts 410 corresponding thereto.

The tenth and eleventh interlayer insulation layers 420 and 430 may be located above the ninth interlayer insulation layer 390. The tenth and eleventh interlayer insulation layers 420 and 430 may electrically isolate the second bit line 450 from the second word lines 400.

Providing the tenth and eleventh interlayer insulation layers 420 and 430 in the semiconductor device, may prevent damage to the semiconductor device during the forming of the second bit line 450. Each of the tenth and the eleventh interlayer insulation layers 420 and 430 may include a layer containing silicon oxide or silicon nitride.

Each of the second via contacts 440 may penetrate the tenth and eleventh interlayer insulation layers 420 and 430 in the vertical direction D3. Each of the second via contacts 440 may include a conductive material such as a metal or a metal nitride, and may electrically connect the second bit line 450 to the second active regions 380.

The second bit line 450 may include a single layer as illustrated in FIG. 2A or may include plurality of layers containing a conductive material. The conductive material may include any suitable conductive material such as, for example, metal nitride, metal, and the like.

FIG. 2B is a cross-sectional view 200b illustrating an example of the semiconductor device taken along a second cutting line B-B′ shown in FIG. 1B according to another embodiment of the disclosed invention.

Referring to FIG. 2B, the semiconductor device may include a substrate layer 510, a first interlayer insulation layer 520 formed over the substrate layer 510, and a second interlayer insulation layer 530 formed over the first interlayer insulation layer 520.

The substrate layer 510 may include a silicon semiconductor material. For example, the substrate layer 510 may include silicon, monocrystalline silicon, polysilicon, amorphous silicon, silicon germanium, monocrystalline silicon germanium, polycrystalline silicon germanium, carbon-doped silicon, and the like.

The substrate layer 510 may include a plurality of control circuits configured to control one or more operations of the semiconductor device. A region of the substrate layer 510 where the control circuits are provided may be referred to as a peripheral circuit region.

The first interlayer insulation layer 520 may include a metal silicide material such as cobalt silicide (CoSi). The first interlayer insulation layer 220 may reduce the operation resistance of the semiconductor device.

The first interlayer insulation layer 520 may protect the substrate layer 210. The first interlayer insulation layer 520 may prevent damage to the substrate layer 210 during a semiconductor fabrication process.

The second interlayer insulation layer 530 may include a layer containing silicon nitride. By including silicon nitride, the second interlayer insulation layer 530 may prevent damage to the substrate layer 510 during a high-temperature semiconductor fabrication process.

The third interlayer insulation layer 540 may be disposed over the second interlayer insulation layer 530. The third interlayer insulation layer 540 may include a layer containing silicon oxide, and the like, may operate as an insulation layer together with the second interlayer insulation layer 530, and may electrically isolate the control circuits included in the substrate layer 210 from the first bit line 250.

The first bit line 550 may be disposed over the third interlayer insulation layer 540. The first bit line 550 may include a plurality of layers. For example, the first bit line 550 may include a first sub-bit line layer 552 including titanium nitride (TiN), a second sub-bit line layer 554 including tungsten (W), and a third sub-bit line layer 556 including titanium nitride (TiN).

Forming the first bit line 550 to include a plurality of layers, allows easier and more effective adjusting of the operation resistance of the semiconductor device to a desirable value.

After depositing the plurality of layers, the first bit line 550 may be formed through an etching process that uses a mask.

Adjacent first bit lines 550 may be electrically isolated from each other by a first bit-line isolation layer (not shown). The first-bit line isolation layer may include a plurality of layers including silicon nitride or silicon oxide.

A fourth interlayer insulation layer 560 and a fifth interlayer insulation layer 570 may be disposed above the first bit line 550.

Each of the fourth interlayer insulation layer 560 and the fifth interlayer insulation layer 570 may include a layer containing at least one of silicon oxide, carbon-containing silicon oxide, and silicon nitride.

As the fourth interlayer insulation layer 560 and the fifth interlayer insulation layer 570 are provided in the semiconductor device, the second sub-gate 580 and the first bit line 550 may be electrically isolated from each other.

The second sub-gate 580 may include a metal, a metal mixture, a metal alloy, titanium nitride, tungsten, polysilicon, or a combination thereof. For example, the second sub-gate 580 may include titanium nitride. The second sub-gate 580 may extend in the second direction D2 shown in FIG. 1B.

The sixth interlayer insulation layer 590 may be disposed between two adjacent second sub-gates 580. The sixth interlayer insulation layer 590 may be a layer that is used as a spacer to form the second sub-gates 580 spaced apart from each other. The sixth interlayer insulation layer 590 may include, for example, silicon oxide. The sixth interlayer insulation layer 590 may extend in the second direction D2 to electrically isolate the two adjacent second sub-gates 580 from each other.

The second sub-gate insulation layer 600 may overlap a sidewall of the vertical portion included in the first active region 610, may overlap upper portions of the second sub-gates 580, may overlap upper portions of the sixth interlayer insulation layers 590, and may electrically isolate the second sub-gate 580 from the vertical portion of the first active region 610.

The second sub-gate insulation layer 600 may include, for example, silicon oxide.

The second sub-gate insulation layer 600 may be formed along a sidewall of the second sub-gate 580 and a top surface of the second sub-gate 580, and may be formed to extend in the second direction D2 shown in FIG. 1B.

At least a portion of the first active region 610 may be arranged to contact the first bit line 550. The horizontal portion included in the first active region 610 may contact the first bit line 550.

The first active region 610 may include two vertical portions and one horizontal portion, and the vertical portion may be formed to extend in the third direction D3 shown in FIG. 1B.

The first active region 610 including two vertical portions and one horizontal portion may be repeatedly arranged in a matrix structure in the first direction D1 and the second direction D2 shown in FIG. 1B.

The first active region 610 may include, for example, an oxide semiconductor material, and the oxide semiconductor material may include indium gallium zinc oxide (IGZO).

In some other embodiments, the first active region 610 may include doped polysilicon, undoped polysilicon, amorphous silicon, indium zinc oxide (IZO), indium tin oxide (ITO), indium oxide (InO₃), and the like.

Since IGZO has low leakage current characteristics and the first active region 610 is formed of IGZO, a semiconductor device with low standby power can be implemented. In addition, since the first active region 610 includes IGZO, fabrication process difficulty may be reduced, and the first active region 610 with a three-dimensional (3D) structure including vertical and horizontal portions may be easily formed.

The source region and the drain region of the first transistor TR1 may be provided in the first active region 610. When an activation voltage is provided to the first sub-gate 630 of the first transistor TR1, a channel region is formed in the first active region 610 so that electron movement may occur between the source region and the drain region.

The first sub-gate insulation layer 620 may be disposed between the first active region 610 and the first sub-gate 630. For example, the first sub-gate insulation layer 620 may include silicon oxide. The first sub-gate 630 and the first active region 610 may be electrically isolated from each other by the first sub-gate insulation layer 620.

The first sub-gate 630 may include a metal, a metal mixture, a metal alloy, titanium nitride, tungsten, polysilicon, or a combination thereof. For example, the first sub-gate 630 and the second sub-gate 580 may include titanium nitride. The first sub-gate 630 may extend in the second direction D2 shown in FIG. 1B.

When the activation voltage is provided to the first sub-gate 630, the same activation voltage as the first sub-gate 630 may be provided to the second sub-gate 580. The activation voltage may be, for example, a first word line activation voltage. In addition, the first word line activation voltage may be provided to the first word line at data read/write time points.

One pair of the first sub-gates 630 and the second sub-gates 580 may operate as one first word line. The vertical portion of the first active region 610 may be disposed between the first sub-gate 630 and the second sub-gate 580 paired with each other.

When the activation voltage corresponding to the first word line activation voltage is provided to the first sub-gate 630 and the second sub-gate 580 adjacent to each other, two channel regions may be formed at both sidewalls of the vertical portion included in the first active region 610.

Since two channel regions are formed, electron mobility may increase, and the semiconductor device can be easily controlled with a low activation voltage.

The semiconductor device according to another embodiment may include the first sub-gate 630 and the second sub-gate 580, thereby implementing an evolved semiconductor device with improved operating current characteristics and higher electron mobility.

The seventh interlayer insulation layer 640 may be disposed between two adjacent first sub-gates 630 to electrically isolate the two adjacent first sub-gates 630 from each other. The seventh interlayer insulation layer 640 may include, for example, silicon oxide or silicon nitride.

The second gate 650 may be arranged to contact one side of the vertical portion included in the first active region 610. The second gate 650 may include a plurality of layers.

For example, the second gate 650 may include a lower gate layer 652 and an upper gate layer 654.

The lower gate layer 652 may include the same material as the first active region 610. For example, the lower gate layer 652 may include an oxide semiconductor such as IGZO.

Since the lower gate layer 652 includes the same material as the first active region 610, the interfacial resistance between the second gate 650 and the first active region 610 can be reduced.

The upper gate layer 654 formed over the lower gate layer 652 may include a conductive material such as a metal nitride or a metal material. Since the characteristics of the material included in the upper gate layer 654 are adjusted, the operation characteristics (e.g., activation voltage, etc.) of the second transistor TR2 can be controlled.

The eighth interlayer insulation layer 660 may be disposed between the second gates 650. The eighth interlayer insulation layer 660 may surround a sidewall of each of the second gates 650. The eighth interlayer insulation layer 660 may electrically isolate adjacent second gates 650 from each other.

The eighth interlayer insulation layer 660 may include, for example, silicon nitride or silicon oxide.

The second gate insulation layer 670 may include an insulation layer formed over the second gates 650. The second gate insulation layer 670 may be disposed to overlap the second gates 650, and may include silicon oxide. The second gates 650 and the second active regions 680 may be electrically isolated from each other by the second gate insulation layer 670.

Each of the second active regions 680 may be shared by two adjacent second transistors TR2. As can be seen from FIG. 2B, one second active region 680 may overlap two second gates 650, and an activation voltage may be provided to the second gates 650 at different time points.

The source region and the drain region of the second transistor TR2 may be provided in each of the second active regions 680. When the activation voltage is provided to the second gates 650 of the second transistor TR2, a channel region may be formed in each of the second active regions 680 so that electron movement may occur between the source region and the drain region of the second active region 680.

In some embodiments, since each of the second transistors TR2 is formed in a vertical shape, the second transistors TR2 can be easily stacked within a small-sized area. In addition, since the second transistor TR2 instead of a capacitor is used as a data storage element, a process of forming the data storage element can be simplified and the degree of freedom of a layout structure of the semiconductor device can be increased.

The ninth interlayer insulation layer 690 may electrically isolate adjacent second active regions 680 from each other. The ninth interlayer insulation layer 690 may include, for example, silicon nitride or silicon oxide.

At least one second word line 700 and at least one first via contact 710 may be formed by etching the ninth interlayer insulation layer 690. Each of the second word lines 700 and each of the first via contacts 710 may include a conductive material such as a metal or a metal nitride. The first via contacts 710 may penetrate the ninth interlayer insulation layer 690 in the vertical direction D3.

The second word lines 700 may extend in the second direction D2 shown in FIG. 1B. The first via contacts 710 may be repeatedly arranged in the first direction D1 and the second direction D2, and each of the second active regions 680 may be connected to the first via contacts 710 corresponding thereto.

The tenth interlayer insulation layer 720 and the eleventh interlayer insulation layer 730 may be located above the ninth interlayer insulation layer 690. The tenth interlayer insulation layer 720 and the eleventh interlayer insulation layer 730 may electrically isolate the second bit line 750 from the second word lines 700.

Since the tenth and eleventh interlayer insulation layers 720 and 730 are provided in the semiconductor device, damage to the semiconductor device may be prevented during the process for forming the second bit line 750. Each of the tenth and eleventh interlayer insulation layers 720 and 730 may include a layer containing silicon oxide or silicon nitride.

Each of the second via contacts 740 may penetrate the tenth interlayer insulation layer 720 and the eleventh interlayer insulation layer 730 in the vertical direction D3. Each of the second via contacts 740 may include a conductive material such as a metal or a metal nitride. Each of the second via contacts 740 may electrically connect the second bit line 750 to the second active regions 680.

The second bit line 750 may include a single layer containing a conductive material as illustrated in FIG. 2B. However, in other embodiments the second bit line 750 may include a plurality of layers containing a conductive material. The conductive material may include, for example, metal nitride, metal, and the like.

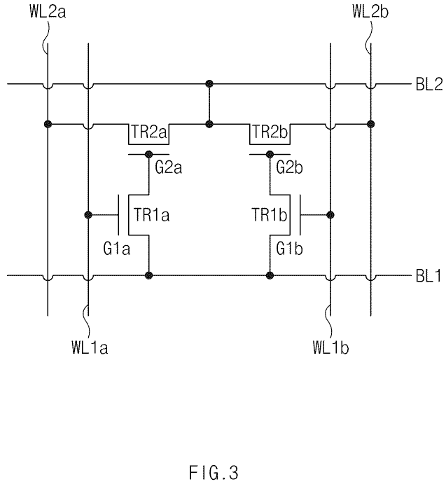

FIG. 3 is an equivalent circuit diagram illustrating a memory cell included in the semiconductor device according to an embodiment of the present disclosure.

Referring to FIG. 3, the memory cell according to an embodiment may include two first transistors TR1a, TR1b and two second transistors TR2a, TR2b. Since the memory cell includes the plurality of first transistors TR1a, TR1b and the plurality of second transistors TR2a, TR2b, damage to data stored in the memory cell can be prevented. Also, the memory cell can perform high-speed read/write operations.

According to another embodiment, the memory cell may be configured to have one first transistor and one second transistor.

The first transistors TR1a, TR1b shown in FIG. 3 may correspond to the first transistor TR1 described in FIGS. 1A, 1B, 2A and 2B, and the second transistors TR2a, TR2b shown in FIG. 3 may correspond to the second transistor TR2 described with reference to FIGS. 1A, 1B, 2A and 2B.

The third gate (G3 of FIG. 1A or 2A) included in the first transistor TR1 described with reference to FIGS. 1A and 2A may serve as a component that electrically isolates the adjacent first word lines WL1a, WL1b from each other, and thus will herein be omitted from the equivalent circuit diagram for convenience of description.

In addition, the first gate G1 illustrated in FIGS. 1A and 1B may be connected to each of the first word lines WL1a, WL1b shown in FIG. 3.

According to the equivalent circuit diagram of the memory cell shown in FIG. 3, two adjacent first transistors TR1a, TR1b may be connected in parallel to each other, and two adjacent second transistors TR2a, TR2b may be connected in series to each other.

According to an embodiment, a memory cell may include a plurality of separate write paths and a plurality of separate read paths.

By way of example, the first word lines WL1a, WL1b may be write word lines, and the first bit line BL1 may be a write bit line. Additionally, the second word lines WL2a, WL2b may be read word lines, and the second bit line BL2 may be a read bit line.

The same signal may be provided to each of the first word lines WL1a, WL1b included in one memory cell.

When a signal corresponding to an activation voltage is provided to the first word lines WL1a, WL1b, the first transistors TR1a, TR1b may be turned on. When the first transistors TR1a, TR1b are turned on, a voltage change may occur in the second gates G2a, G2b due to the voltage provided to the first bit line BL1. At this time, the type of data (e.g., 0 or 1) stored in the second gates G2a, G2b may be determined depending on the voltage provided to the first bit line BL1. The above operation may be referred to as a write operation.

When a signal other than the activation voltage is provided to the first word lines WL1a, WL1b, the first transistors TR1a, TR1b may be turned off. When the first transistors TR1a, TR1b are turned off, the on/off actions of the second transistors TR2a, TR2b may be determined based on the voltage change that has occurred in the second gates G2a, G2b during the write operation. During the read operation, the activation voltage may be provided to the second word lines WL2a, WL2b. Accordingly, when the second transistors TR2a, TR2b are turned on, a signal corresponding to the activation voltage may be output through the second bit line BL2, and when the second transistors TR2a, TR2b are turned off, a signal corresponding to a deactivation voltage may be output through the second bit line BL2. The operation of outputting the above signal corresponding to the voltage change that has occurred in the second gates G2a, G2b during the write operation may hereinafter be referred to as a read operation.

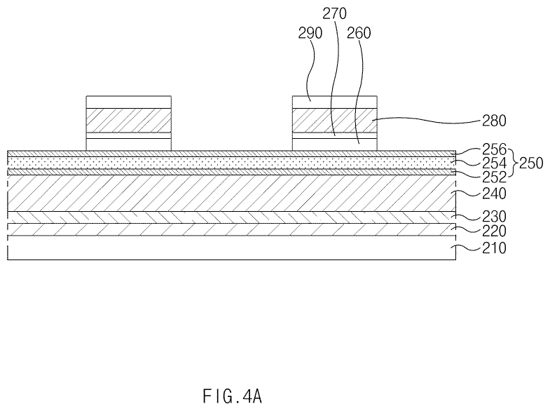

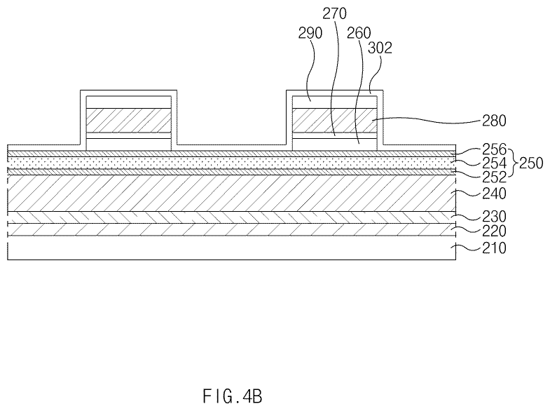

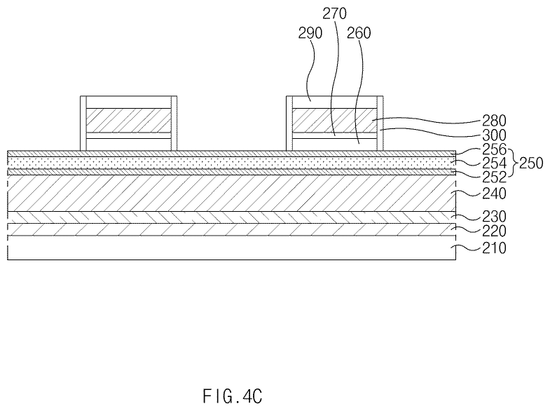

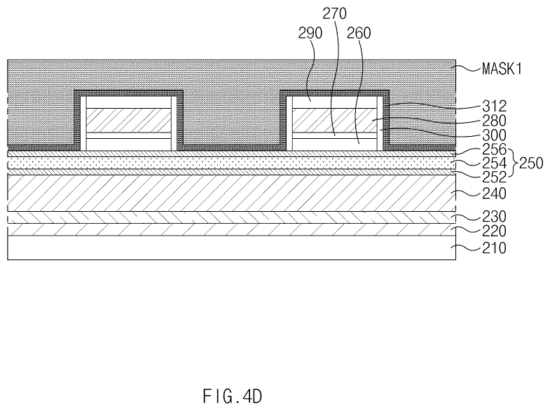

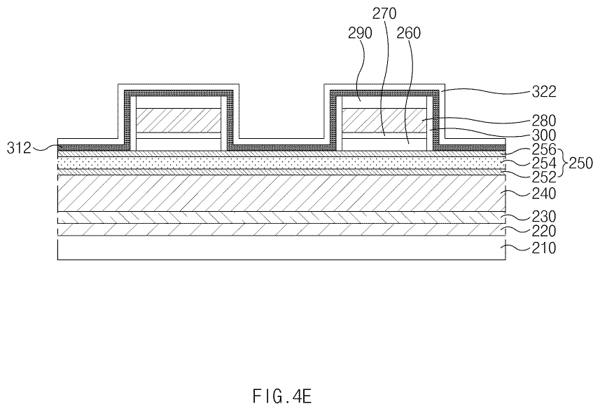

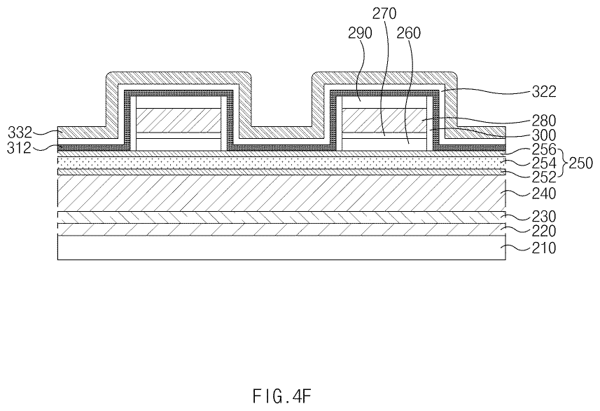

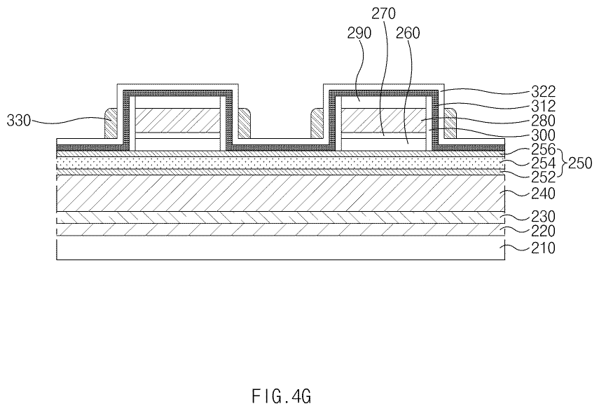

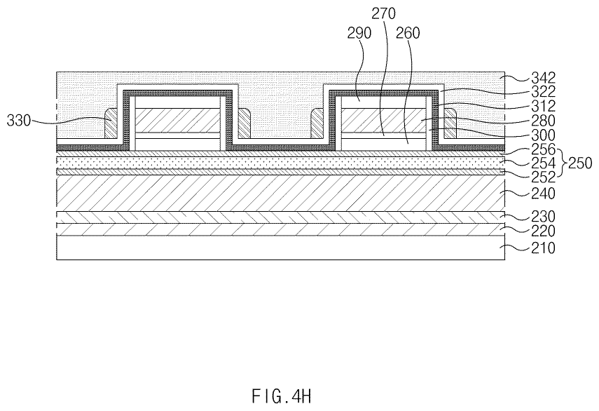

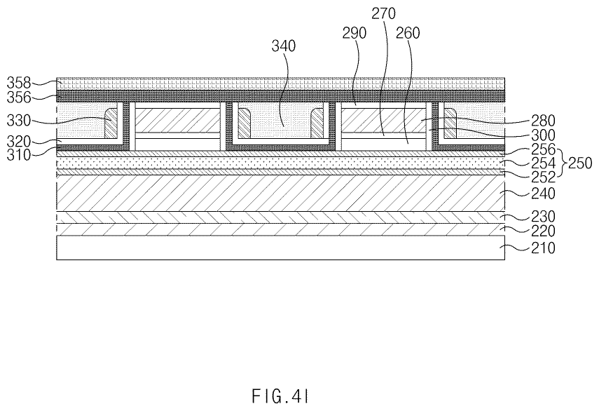

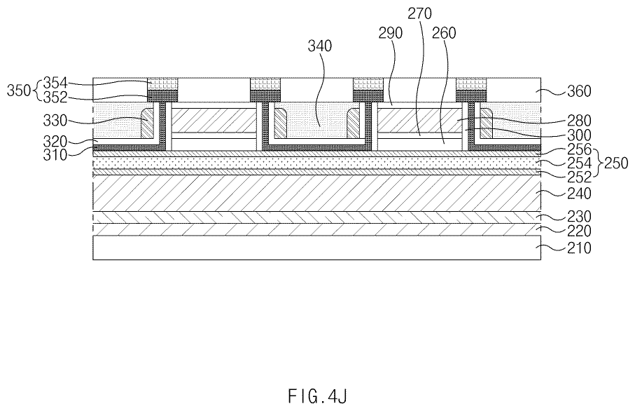

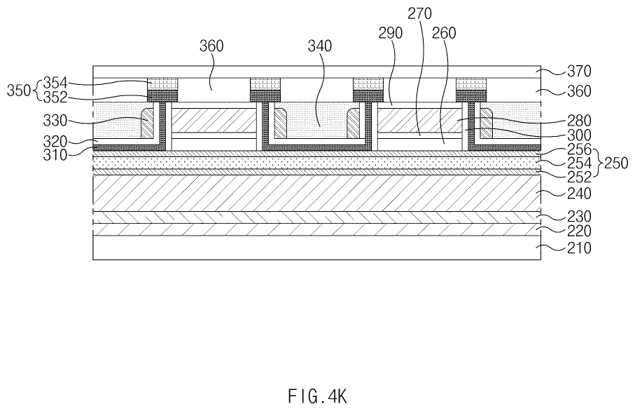

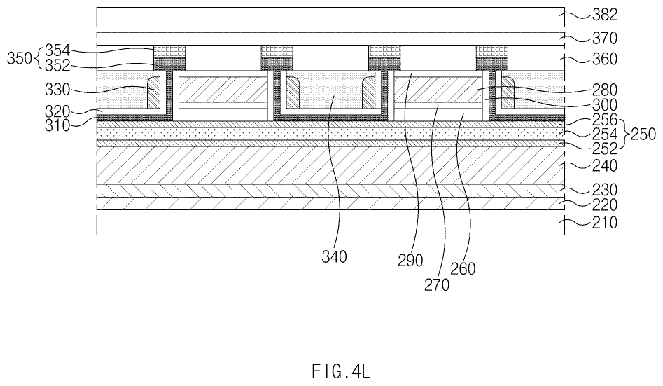

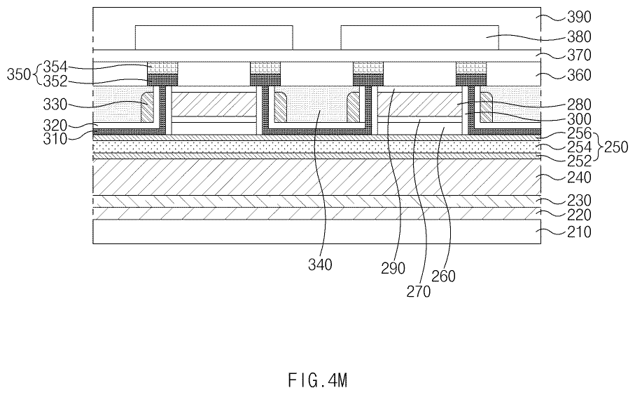

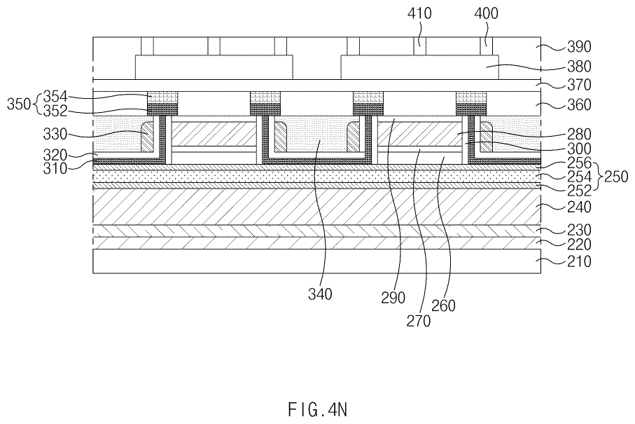

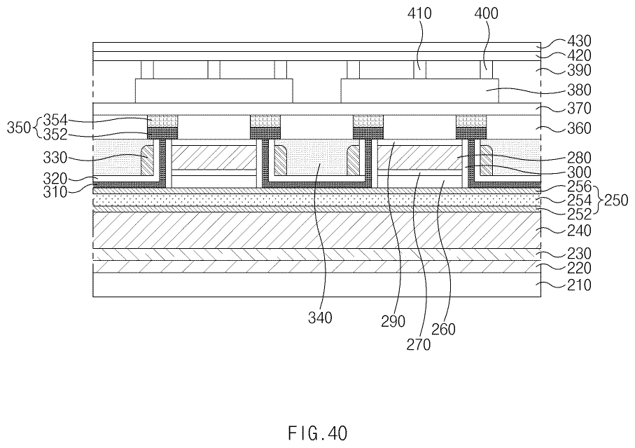

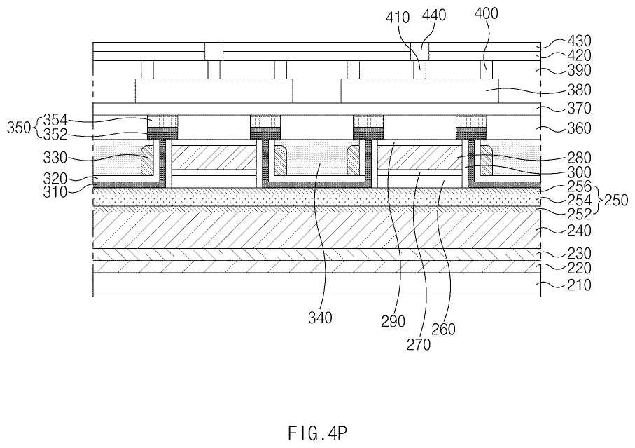

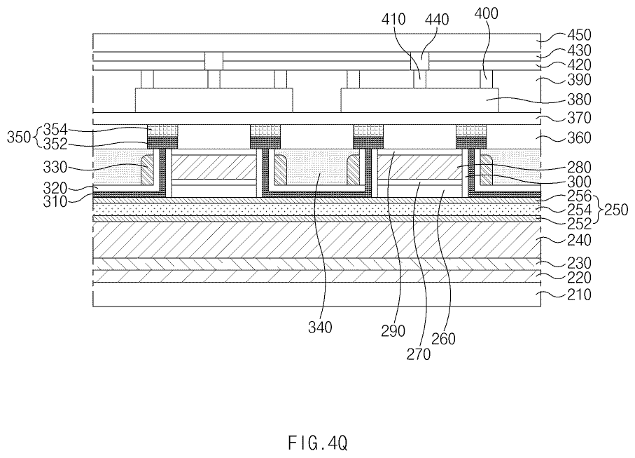

FIGS. 4A to 4Q are cross-sectional views illustrating a method for manufacturing the semiconductor device according to an embodiment of the present disclosure.

A process for forming a fourth interlayer insulation layer 260, a fifth interlayer insulation layer 270, a third gate 280, and a sixth interlayer insulation layer 290 on the first bit line 250 will hereinafter be described with reference to FIG. 4A.

A plurality of insulation layers, a conductive material layer, and a mask layer are provided on the first bit line 250, and are then partially etched, so that the fourth interlayer insulation layer 260, the fifth interlayer insulation layer 270, the third gate 280, and the sixth interlayer insulation layer 290 may be formed.

Each of the fourth interlayer insulation layer 260 and the fifth interlayer insulation layer 270 may be a layer that contains at least one of silicon oxide, carbon-containing silicon oxide and silicon nitride, and may electrically isolate the first bit line 250 and the third gate 280 from each other.

The sixth interlayer insulation layer 290 formed over the third gate 280 may be a mask for selectively etching the third gate 280. The sixth interlayer insulation layer 290 may include silicon nitride. The third gate 280 may extend in a direction perpendicular to the first bit line 250. The fourth interlayer insulation layer 260, the fifth interlayer insulation layer 270, and the sixth interlayer insulation layer 290 may also extend in a direction perpendicular to the first bit line 250.

A process for forming a third pre-gate insulation layer 302 overlapping with the sixth interlayer insulation layer 290 and the first bit line 250 will hereinafter be described with reference to FIG. 4B.

The third pre-gate insulation layer 302 may contact a sidewall of the third gate 280. The third pre-gate insulation layer 302 may also be disposed to overlap the sixth interlayer insulation layer 290 and the top of the first bit line 250. The third pre-gate insulation layer 302 may include silicon oxide.

FIG. 4C illustrates an operation for forming the third gate insulation layer 300 by selectively etching the third pre-gate insulation layer 302.

Referring to FIG. 4C, by selectively etching the third pre-gate insulation layer 302, a third gate insulation layer 300 may be formed to electrically isolate the third gate 280 from the adjacent first active region 310.

In addition, the third pre-gate insulation layer 302 overlapping at least a portion of the first bit line 250 may be removed to allow the first active region 310 to be electrically connected to the first bit line 250.

FIG. 4D illustrates an operation for forming the first pre-active region 312 by forming an oxide semiconductor layer and selectively etching the oxide semiconductor layer using a first mask MASK1.

Referring to FIG. 4D, the oxide semiconductor layer may overlap the first bit line 250, the sixth interlayer insulation layer 290, and the third gate insulation layer 300. The oxide semiconductor layer may include an oxide semiconductor material such as IGZO.

By selectively etching the oxide semiconductor layer using the first mask MASK1, the first pre-active regions 312 may be isolated from each other in the second direction (e.g., D2 in FIG. 1A). The first mask MASK1 may include Spin on Carbon (SOC) and SiON layers.

The thickness and physical properties of the first active region 310 may be adjusted by forming the oxide semiconductor layer through an atomic layer deposition (ALD) process.

FIG. 4E illustrates an operation for forming the first pre-gate insulation layer 322 on the first pre-active region 312.

Referring to FIG. 4E, the first pre-gate insulation layer 322 may be formed over the first pre-active region 312, so that the first active region 310 and the first gate 330 may be electrically isolated from each other. The first pre-gate insulation layer 322 may include, for example, silicon oxide.

FIG. 4F illustrates an operation for forming the first pre-gate 332 on the first pre-gate insulation layer 322.

The first pre-gate 332 may include a conductive material such as a metal nitride. For example, the first pre-gate 332 may include titanium nitride.

FIG. 4G illustrates an operation for forming the first gate 330 by selectively etching the first pre-gate 332.

Referring to FIG. 4G, the first gate 330 may be isolated from the first pre-active region 312 by the first pre-gate insulation layer 322.

FIG. 4H illustrates an operation for forming the seventh pre-interlayer insulation layer 342. The seventh pre-interlayer insulation layer 342 may be formed to cover a structure obtained in FIG. 4G. The seventh pre-interlayer insulation layer 342 may be formed on the first gate 330.

The seventh pre-interlayer insulation layer 342 may include an insulation material such as silicon nitride or silicon oxide. The seventh pre-interlayer insulation layer 342 may electrically isolate adjacent first gates 330 from each other.

FIG. 4I illustrates an operation for forming the first active region 310 and then forming a pre-lower gate layer 356 and a pre-upper gate layer 358 on the first active region 310.

Referring to FIG. 41, a first active region 310 is formed, and a pre-lower gate layer 356 and a pre-upper gate layer 358 are formed on the first active region 310.

Through an etching process, a partial region of the seventh pre-interlayer insulation layer 342, a partial region of the first pre-gate insulation layer 322, and a partial region of the first pre-active region 312 may be removed to form the first active region 310, the first gate insulation layer 320, and the seventh interlayer insulation layer 340.

By etching the first pre-active region 312, the first active regions 310 adjacent to each other in the first direction (e.g., D1 in FIG. 1A) may be isolated from each other.

The pre-lower gate layer 356 formed over the first active region 310 may include the same material as the first active region 310. For example, the pre-lower gate layer 356 may include an oxide semiconductor such as IGZO.

Since the pre-lower gate layer 356 is formed of the same material as the first active region 310, contact resistance between the second gate 350 and the first active region 310 may be reduced.

The pre-upper gate layer 358 formed over the pre-lower gate layer 356 may include a conductive material such as a metal nitride. By adjusting the type of constituent materials of the pre-upper gate layer 358, a work function of the second gate 350 can be controlled and the electrical properties of the second transistor TR2 can be adjusted.

FIG. 4J illustrates an operation for forming the second gate 350.

Referring to FIG. 4J, the second gate 350 may be formed by removing the pre-lower gate layer 356 and the pre-upper gate layer 358 except for the area where the second gate 350 is formed through an etching process, and then depositing the eighth interlayer insulation layer 360.

Adjacent second gates 350 may be isolated from each other by the eighth interlayer insulation layer 360. The sidewalls of the second gates 350 may be surrounded by the eighth interlayer insulation layer 360, and the area where the second gate 350 is disposed may be defined by the eighth interlayer insulation layer 360.

The eighth interlayer insulation layer 360 may include, for example, silicon nitride or silicon oxide.

FIG. 4K illustrates an operation for forming the second gate insulation layer 370 on the second gates 350.

Referring to FIG. 4K, the second gate insulation layer 370 is disposed on the second gates 350. The second gate insulation layer 370 may include an insulation material such as silicon oxide or silicon nitride.

According to another embodiment, the second gate insulation layer 370 may include a high-k material. By adjusting a dielectric constant of the second gate insulation layer 370, the electrical properties such as a leakage current and a threshold voltage of the second transistor TR2 may be adjusted.

FIG. 4L illustrates an operation for forming the second pre-active region 382 on the second gate insulation layer 370.

Referring to FIG. 4L, the second pre-active region 382 may include the same oxide semiconductor material as the first active region 310. The second pre-active region 382 may be formed through an atomic layer deposition (ALD) process. As the second pre-active region 382 is formed through the ALD process, a thickness of the second active region 380 may be easily adjusted.

FIG. 4M illustrates an operation for forming the second active region 380 using the second pre-active region 382 and forming the ninth interlayer insulation layer 390 on the second active region 380.

Referring to FIG. 4M, the second active region 380 may be selectively formed in a preset region through an etching process. For example, each of the second active regions 380 may be formed to overlap upper portions of two adjacent second gates 350.

According to another embodiment, each of the second active regions 380 may be formed to overlap one second gate 350 or may be formed to overlap four adjacent second gates 350.

Depending on where the second active region 380 is formed, the connection relationship and number of second transistors included in one memory cell may vary. The second transistors sharing the second active region 380 may be second transistors included in one memory cell.

The ninth interlayer insulation layer 390 may electrically isolate the second active regions 380 from each other. The ninth interlayer insulation layer 390 may include an insulation layer such as silicon oxide or silicon nitride.

FIG. 4N illustrates an operation for forming second word lines 400 and first via contacts 410 connected to the second active regions 380.

Referring to FIG. 4N, the second word lines 400 and the first via contact 410 may be formed by selectively etching the ninth interlayer insulation layer 390 using a mask. Each of the second word lines 400 may have a shape extending in the second direction (e.g., D2 in FIG. 1A). Each of the first via contacts 410 may overlap the second active region 380 and may have a shape extending in the vertical direction (e.g., D3 in FIG. 1A).

The second word lines 400 may be commonly connected to a plurality of second active regions 380 repeatedly arranged in the second direction (e.g., D2 in FIG. 1A). On the other hand, the first via contact 410 may be connected to only one second active region 380.

The first via contact 410 and the second word line 400 may include conductive materials such as a metal or a metal nitride, and depending on the embodiment, the conductive materials may have a stacked structure.

FIG. 40 illustrates an operation for forming the tenth and eleventh interlayer insulation layers 420 and 430 on the ninth interlayer insulation layer 390.

Referring to FIG. 40, each of the tenth and eleventh interlayer insulation layers 420 and 430 may contain silicon oxide or silicon nitride. By forming the tenth and eleventh interlayer insulation layers 420 and 430, damage to the semiconductor device during the process for forming the second bit line 450 may be prevented.

FIG. 4P illustrates an operation for forming the second via contacts 440 on the tenth and eleventh interlayer insulation layers 420 and 430.

Referring to FIG. 4P, the second via contacts 440 may be formed by selectively etching the tenth and eleventh interlayer insulation layers 420 and 430. The second via contact 440 may overlap the first via contact 410. Each of the second via contacts 440 may be disposed to be connected to only one second active region 380 in the same manner as the first via contact 410.

The second via contact 440 may include a conductive material such as a metal or a metal nitride.

FIG. 4Q illustrates an operation for forming the second bit line 450 on the second via contact 440 and the eleventh interlayer insulation layer 430.

Referring to FIG. 4Q, each of the second bit lines 450 may have a structure extending in a first direction (e.g., D1 in FIG. 1A). In addition, adjacent second bit lines 450 may be arranged spaced apart from each other in the second direction (e.g., D2 in FIG. 1A).

The second bit line 450 may be formed by selectively etching the conductive material layer. Damage to the semiconductor device during the etching process for forming the second bit line 450 can be prevented by the tenth and eleventh interlayer insulation layers 420 and 430.

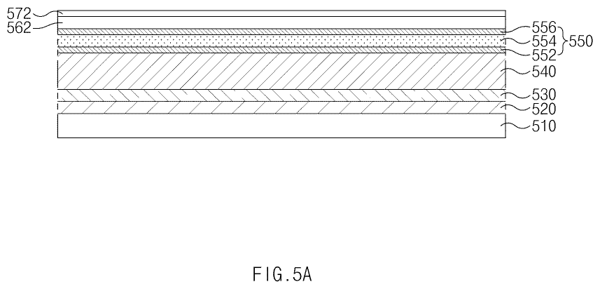

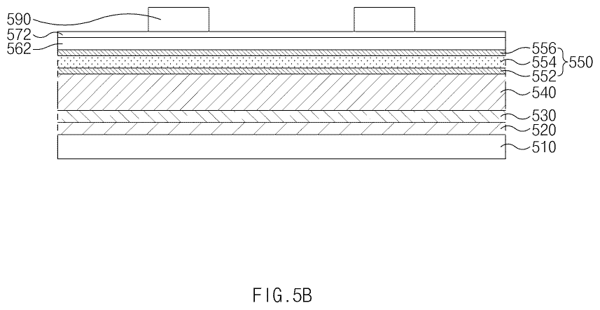

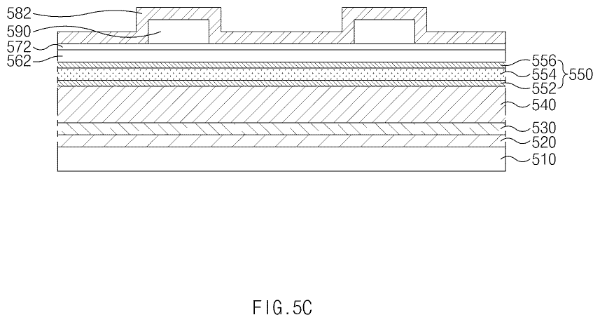

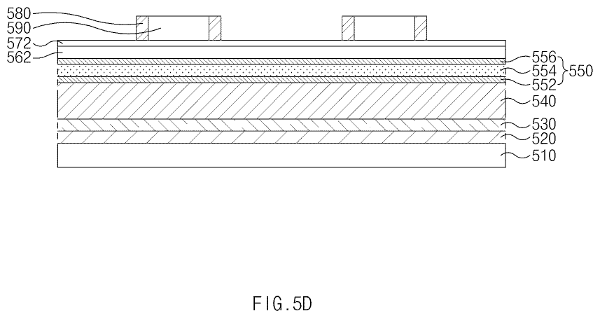

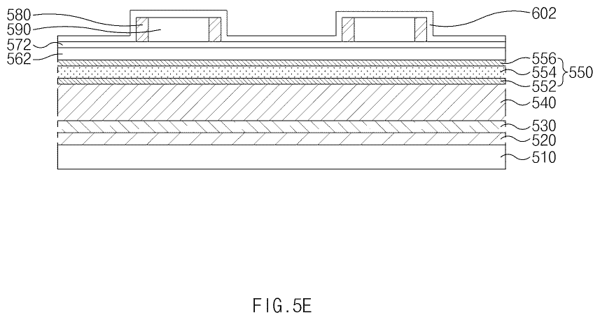

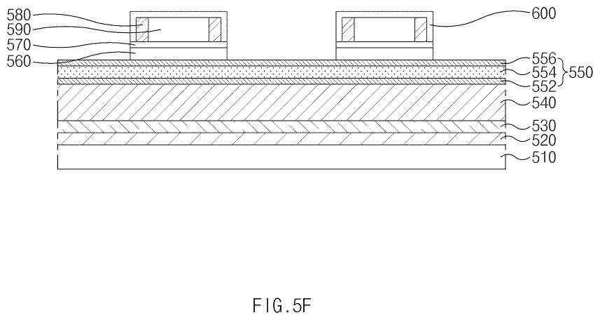

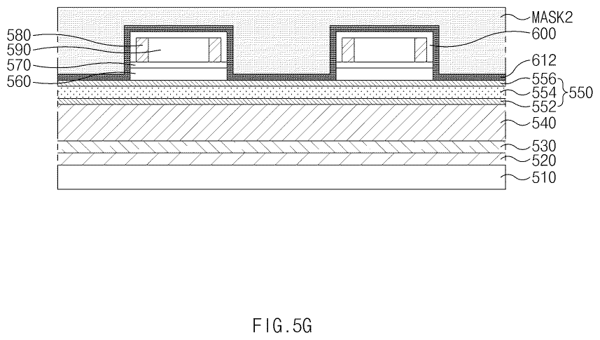

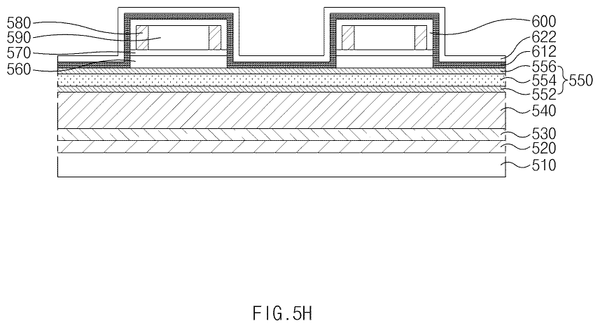

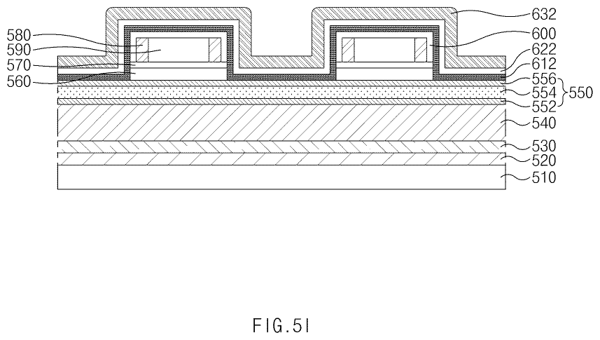

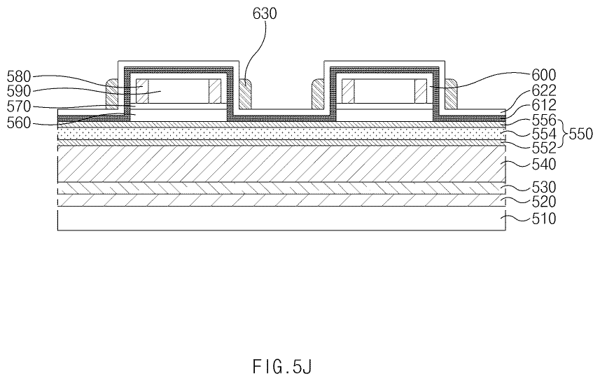

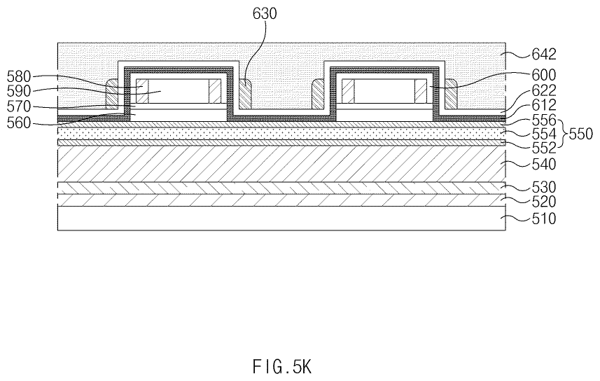

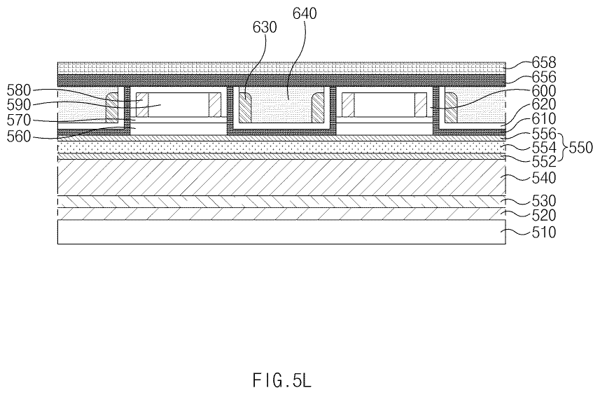

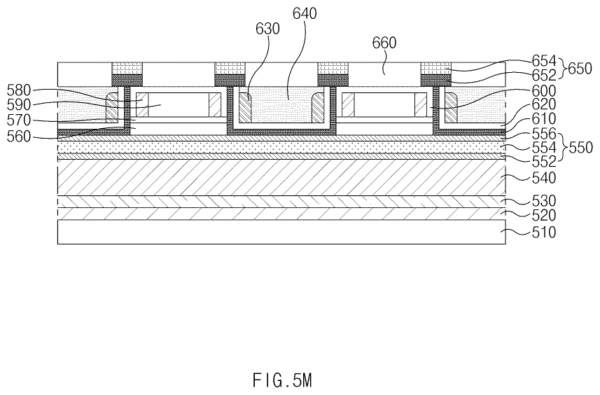

FIGS. 5A to 5M are cross-sectional views illustrating a method for manufacturing the semiconductor device according to another embodiment of the present disclosure.

FIG. 5A illustrates an operation for forming the fourth pre-interlayer insulation layer 562 and a fifth pre-interlayer insulation layer 572 on the first bit line 550.

Referring to FIG. 5A, the fourth pre-interlayer insulation layer 562 and the fifth pre-interlayer insulation layer 572 may prevent damage to the first bit line 550 during the process of manufacturing the semiconductor device.

The fourth pre-interlayer insulation layer 562 and the fifth pre-interlayer insulation layer 572 may contain at least one of silicon oxide, carbon-containing silicon oxide, and silicon nitride.

FIG. 5B illustrates an operation for forming the sixth interlayer insulation layer 590 on the fifth pre-interlayer insulation layer 572.

Referring to FIG. 5B, the sixth interlayer insulation layer 590 may be configured to electrically isolate adjacent second sub-gates 580 from each other, and may extend in the second direction (e.g., D2 in FIG. 1B).

The sixth interlayer insulation layer 590 may include, for example, silicon oxide, and may be formed by etching the silicon oxide layer formed on the fifth pre-interlayer insulation layer 572.

FIG. 5C illustrates an operation for forming the second pre-sub gate 582 on the sixth interlayer insulation layer 590.

Referring to FIG. 5C, the second pre-sub gate 582 may include a conductive material such as a metal or a metal nitride, and may be a region to be used as the second sub-gate 580 through a subsequent etching process.

FIG. 5D illustrates an operation for forming the second sub-gate 580 from the second pre-sub gate 582.

Referring to FIG. 5D, the second sub-gate 580 may extend in the second direction (e.g., D2 in FIG. 1B), and may be disposed along both sidewalls of the sixth interlayer insulation layer 590.

FIG. 5E illustrates an operation for forming the second pre-sub gate insulation layer 602 over the second sub-gates 580 and the sixth interlayer insulation layers 590.

Referring to FIG. 5E, the second pre-sub gate insulation layer 602 may include an insulation material such as silicon oxide or silicon nitride. The second pre-sub gate insulation layer 602 may electrically isolate the second sub-gates 580 from other adjacent layers.

FIG. 5F illustrates an operation for etching the second pre-sub gate insulation layer 602, the fourth pre-interlayer insulation layer 562, and the fifth pre-interlayer insulation layer 572.

Referring to FIG. 5F, by etching the second pre-sub gate insulation layer 602, the fourth pre-interlayer insulation layer 562, and the fifth pre-interlayer insulation layer 572, a portion of the first bit line 550 may be exposed outside, and the first active region 610 formed on the bit line 550 may be connected to the first bit line 550.

The second sub-gate insulation layer 600, the fourth inter-layer insulation layer 560, and the fifth interlayer insulation layer 570 may be formed by etching the second pre-sub gate insulation layer 602, the fourth pre-interlayer insulation layer 562, and the fifth pre-interlayer insulation layer 572.

FIG. 5G illustrates an operation for forming an oxide semiconductor layer and selectively etching the oxide semiconductor layer using a second mask MASK2 to form a first pre-active region 612.

Referring to FIG. 5G, the oxide semiconductor layer may overlap with the entirety of the first bit line 550 and the second sub-gate insulation layer 600, and may include an oxide semiconductor material such as IGZO.

By selectively etching the oxide semiconductor layer using the second mask MASK2, the first pre-active regions 612 may be isolated from each other in the second direction (e.g., D2 in FIG. 1B). The second mask MASK2 may include Spin on Carbon (SOC) and SiON layers.

The thickness and physical properties of the first active region 610 may be adjusted by forming the oxide semiconductor layer through the atomic layer deposition (ALD) process.

FIG. 5H illustrates forming the first pre-sub gate insulation layer 622 on the first pre-active region 612.

Referring to FIG. 5H, since the first pre-sub gate insulation layer 622 is formed over the first pre-active region 612, the first active region 610 and the first sub-gate 630 may be electrically isolated from each other. The first pre-sub gate insulation layer 622 may include, for example, silicon oxide.

FIG. 5I illustrates an operation for forming the first pre-sub gate 632 on the first pre-sub gate insulation layer 622.

The first pre-sub gate 632 may include a conductive material such as a metal nitride. For example, the first pre-sub gate 632 may include titanium nitride.

FIG. 5J illustrates forming the first sub-gate 630 by selectively etching the first pre-sub gate 632.

Referring to FIG. 5J, the first sub-gate 630 may be isolated from the first pre-active region 612 by a first pre-sub gate insulation layer 622.

FIG. 5K illustrates forming the seventh pre-interlayer insulation layer 642 on the first sub-gate 630.

Referring to FIG. 5K, the seventh pre-interlayer insulation layer 642 may include an insulation material such as silicon nitride or silicon oxide, and may electrically isolate adjacent first sub-gates 630 from each other.

FIG. 5L illustrates an operation for forming the first active region 610 and then forming the pre-lower gate layer 656 and the pre-upper gate layer 658 over the first active region 610.

Referring to FIG. 5L, through an etching process, a partial region of the seventh pre-interlayer insulation layer 642, a partial region of the first pre-sub gate insulation layer 622, and a partial region of the first pre-active region 612 are removed to form the first active region 610, the first sub-gate insulation layer 620, and the seventh interlayer insulation layer 640.

By etching the first pre-active region 612, adjacent first active regions 610 adjacent to each other in the first direction (e.g., D1 in FIG. 1B) may be isolated from each other.

The pre-lower gate layer 656 formed over the first active region 610 may include the same material as the first active region 610. For example, the pre-lower gate layer 656 may include an oxide semiconductor such as IGZO.

Since the pre-lower gate layer 656 is formed of the same material as the first active region 610, contact resistance between the second gate 650 and the first active region 610 may be reduced.

The pre-upper gate layer 658 formed over the pre-lower gate layer 656 may include a conductive material such as a metal nitride. By adjusting the type of constituent materials of the pre-upper gate layer 658, a work function of the second gate 650 can be controlled and the electrical properties of the second transistor TR2 can be adjusted.

FIG. 5M illustrates an operation for forming the second gate 650.

Referring to FIG. 5M, the second gate 650 may be formed by removing the pre-lower gate layer 656 and the pre-upper gate layer 658 except for the area where the second gate 650 is formed through an etching process, and then depositing the eighth interlayer insulation layer 660.

Adjacent second gates 650 may be isolated from each other by the eighth interlayer insulation layer 660. The sidewalls of the second gates 350 may be surrounded by the eighth interlayer insulation layer 660, and the area where the second gate 650 is disposed may be defined by the eighth interlayer insulation layer 660.

The eighth interlayer insulation layer 360 may include, for example, silicon nitride or silicon oxide.

The process of forming the second active region over the second gate 650 and then forming the second word line and the second bit line may be substantially the same as the process described with reference to FIGS. 4K to 4Q, and as such redundant description thereof will herein be omitted for brevity.

As is apparent from the above description, the semiconductor device based on some embodiments of the present disclosure includes three-dimensional (3D) channels to improve the degree of integration.

Additionally, the semiconductor device based on some embodiments of the present disclosure includes at least one transistor that operates as a storage element, resulting in a simplified fabrication process.

The embodiments of the present disclosure may provide a variety of effects capable of being directly or indirectly recognized. Those skilled in the art will appreciate that the

embodiments of the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Furthermore, the embodiments may be combined to form additional embodiments.

What is claimed is:

1. A semiconductor device comprising:
a first bit line extending in a first direction;
a first transistor including a first gate that extends in a second direction perpendicular to the first direction and a first active region;
a second bit line extending in the first direction; and
a second transistor including a second active region connected to the second bit line and a second gate overlapping with the second active region,
wherein
the first active region includes:
a horizontal portion in contact with the first bit line; and
a vertical portion in contact with the horizontal portion and extending in a third direction perpendicular to each of the first direction and the second direction, and
the second gate is in contact with the vertical portion.

2. The semiconductor device according to claim 1, wherein the first gate is connected to a first word line.

3. The semiconductor device according to claim 2, further comprising:
a second word line extending in the second direction,
wherein
the second word line is connected to the second active region.

4. The semiconductor device according to claim 1, wherein the second transistor is configured to share the second active region with another adjacent second transistor.

5. The semiconductor device according to claim 4, wherein the second gates included in the second transistors sharing the second active region are in contact with vertical portions of different first transistors, respectively.

6. The semiconductor device according to claim 1, wherein
source and/or drain regions of the first transistor are included in the first active region; and
source and/or drain regions of the second transistor are included in the second active region.

7. The semiconductor device according to claim 6, wherein:
source and/or drain regions of the first transistor are connected to either the second gate or the first bit line; and
source and/or drain regions of the second transistor are connected to either the second bit line or a second word line extending in the second direction.

8. The semiconductor device according to claim 1, further comprising:
a plurality of memory cells, each of which includes two first transistors and two second transistors.

9. The semiconductor device according to claim 8, wherein:
the two first transistors are connected in parallel to each other; and
the two second transistors are connected in series to each other.

10. The semiconductor device according to claim 1, wherein
each of the first active region and the second active region includes indium gallium zinc oxide (IGZO).

11. The semiconductor device according to claim 1, further comprising:
a third gate disposed between vertical portions respectively included in adjacent first active regions, and extending in the second direction.

12. The semiconductor device according to claim 11, wherein the third gate is configured to receive a ground voltage as an input.

13. The semiconductor device according to claim 1, wherein:
the first gate includes a first sub-gate and a second sub-gate extending in the second direction; and
the vertical portion is disposed between the first sub-gate and the second sub-gate.

14. The semiconductor device according to claim 13, wherein
the same activation voltage is provided to the first sub-gate and the second sub-gate.

15. The semiconductor device according to claim 1, further comprising:
a first gate insulation layer disposed between the first gate and the first active region; and
a second gate insulation layer disposed between the second gate and the second active region.

16. The semiconductor device according to claim 1, wherein
the second active region is connected to the second bit line through a via contact.

17. A semiconductor device comprising:
a first bit line extending in a first direction;
a first gate extending in a second direction perpendicular to the first direction;
a first active region configured to include a vertical portion extending in a third direction perpendicular to each of the first direction and the second direction, and a horizontal portion extending in the first direction while contacting the first bit line;
a first gate insulation layer disposed between the first gate and the first active region;
a second gate in contact with the vertical portion;
a second gate insulation layer disposed over the second gate;
a second active region disposed over the second gate insulation layer;
a second bit line extending in the first direction and connected to the second active region; and
a second word line extending in the second direction and connected to the second active region.

18. The semiconductor device according to claim 17, further comprising:
another first active region in contact with the first bit line while having the same shape as the first active region; and
another second gate in contact with the other first active region,
wherein
the second gate insulation layer is disposed between the second active region and the other second gate.

19. The semiconductor device according to claim 18, further comprising:
another first gate extending in the second direction; and
another first gate insulation layer disposed between the other first gate and the other first active region.

20. The semiconductor device according to claim 19, further comprising:
a third gate disposed between the first active region and the other first active region, and extending in the second direction.

21. The semiconductor device according to claim 17, further comprising:
another second word line extending in the second direction and connected to the second active region.
